(19) United States
(12) Patent Application Publication
(10) Pub. No.: US 2006/0162899 A1
(43) Pub. Date: Jul. 27, 2006

(54) Structure of liquid cooled waterblock with thermal conductivities

(76) Inventors: Wei Cheng Huang, Taipei (TW); Sung-Lin Hsu, Taipei (TW)

Correspondence Address: BACON & THOMAS, PLLC, 625 SLATERS LANE, FOURTH FLOOR, ALEXANDRIA, VA, 22314, US

(21) Appl. No.: 11/042,047

(22) Filed: Jan. 26, 2005

(51) Int. Cl. H05K 7/20

(52) U.S. Cl. 165/80.4; 361/699

(57) ABSTRACT

The present invention is a structure of liquid cooled waterblock with thermal conductivities. More specifically, it is used in a waterblock, which is employed by the liquid cooled thermal dissipation system of chip on the computer's main unit. The waterblock includes an upper cover and a body, in which multiple thermal conductivities are provided at the upper and lower sides of the upper cover to conduct thermal radiation. The lower conductivities are setted at the containing slot inside the body such that not only turbulent flow of liquid in the waterblock is formed, but the thermal generated by the chip is conducted to the upper cover and dissipated by the fan as well. Simultaneously, part of the thermal is conducted from the thermal conductivities to liquid, and then brought to the radiator through the circulating flow of liquid to perform thermal radiation.

### BACKGROUND OF THE INVENTION

1) Field of the Invention

This invention is a structure of liquid cooled waterblock with thermal conductivities. More specifically, it is used in a liquid cooled thermal dissipation system to perform thermal exchange when attached on the chip inside a computer's main unit.

2) Description of the Prior Art

Computer technologies have been developed fast recently. In accordance with the advance of main unit's operation speed, the thermal generated by chips becomes a problem. Therefore the technology of thermal dissipation becomes an important issue. As the existing technology of air cooled thermal dissipation is unable to meet the requirement of thermal dissipation. Miscellaneous liquid cooled thermal dissipation systems are emerging accordingly.

A conventional liquid cooled thermal dissipation system is shown in FIG. 1. The modules constructing a liquid cooled thermal dissipation system include a pump 1, a waterblock 2′, a fan 3, a radiator 4, input and output pipe. 24, 25, in which waterblock 2′ is attached on the operating chip 5, while pipes 24, 25 input/output liquid to/from waterblock 2′ and bring liquid through radiator 4 to pump 1 to complete a circulation. Basically, the conventional waterblock 2′ simply transmits the thermal generated by operating chip 5 to radiatior 4 by way of liquid of waterblock 2′, then the thermal is radiated by the fan 3. Since the waterblock 2′ itself is not effective in thermal exchange because limited fraction of thermal can be dissipated, the performance of whole system in terms of thermal dissipation is correspondingly poor when operating chip 5 generates enormous thermal.

In a conventional structure, it is not sufficient that the whole liquid cooled thermal dissipation system depends entirely on radiator 4 and fan 3 for thermal dissipation.

The performance can be improved if a first cooling step is carried out immediately next to the thermal source (i.e., waterblock is attached to the operating chip), and then liquid is sent to radiator 4 to carry out the second cooling step. Consequently, the rate of thermal dissipation is improved, the load of radiator 4 to dissipate thermal is relaxed, and the efficiency of whole liquid cooled thermal dissipation system is enhanced.

### SUMMARY OF THE INVENTION

Based on this observation, to enhance the ability of liquid cooled thermal dissipation system, the present invention introduces a design with the upper and lower thermal conductivities provided at the upper cover of waterblock, and an additional fan is installed to enforce thermal dissipation. In our design, the lower thermal conductivities are inserted in and contacted to the containing slots inside the body such that turbulent flow of liquid in the waterblock is formed, and simultaneously part of the thermal can be conducted to the upper thermal conductivities, while the rest of thermal is conducted through the lower conductivities to liquid, and by way of a pump, the liquid is circulated through input and output pipes, and then sent to radiator for thermal exchange. and then radiated by the fan installed on the top of wartblock in a liquid cooled thermal dissipation system thus augments the effect of thermal dissipation.

The detailed description and technical contents of the present invention together with the accompanying drawings are described in the following.

### BRIEF DESCRIPTION OF THE DRAWINGS

FIG. 1 is a pictorial drawing showing a conventional liquid cooled thermal dissipation system.

FIG. 2 is a pictorial drawing showing the structure of liquid cooled thermal dissipation system according to the present invention.

FIG. 3 is an exploded view of the present invention.

FIG. 4 is a sectional side view of the present invention.

FIG. 5 is a sectional side view of another embodiment according to the present invention.

FIG. 6 shows an embodiment side view of another embodiment according to the present invention.

FIG. 7 shows another embodiment side view of another embodiment according to the present invention.

FIG. 8 shows yet another embodiment side view of another embodiment according to the present invention.

FIG. 9 shows an embodiment side view of another embodiment according to the present invention.

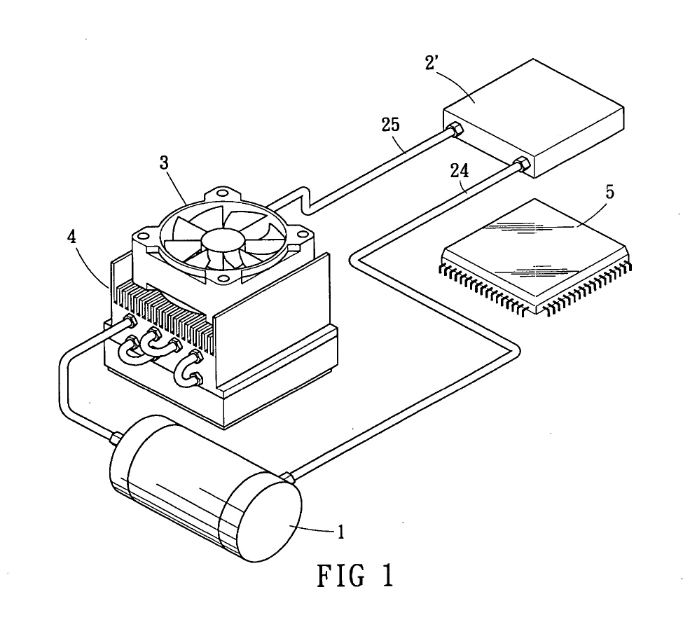

### DETAILED DESCRIPTION OF THE PREFERRED EMBODIMENTS

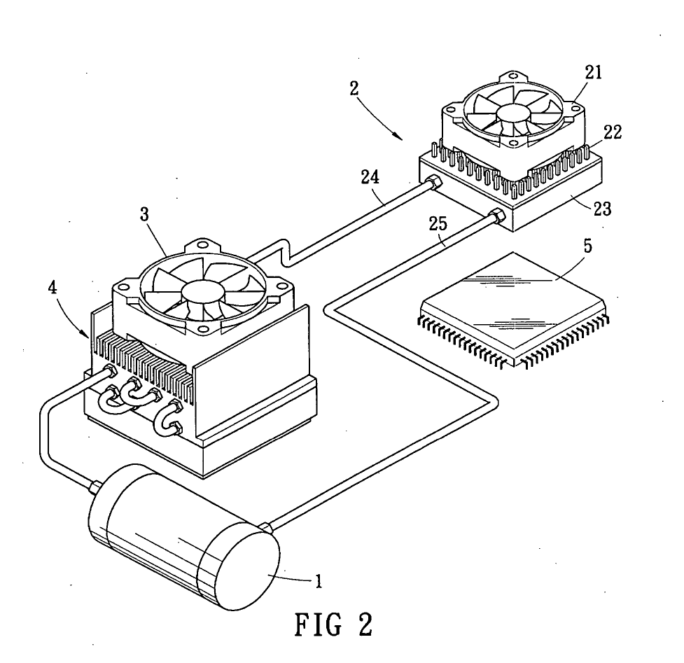

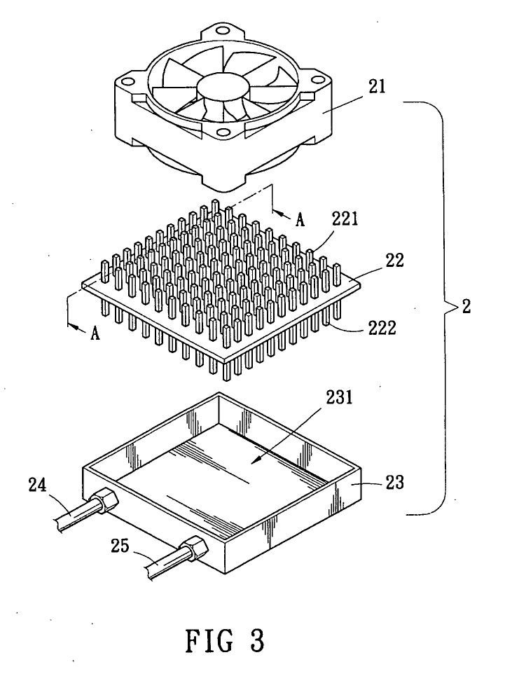

Referring to FIG. 2 and FIG. 3, where the upper cover 22 is closely mated with the body 23 to form a waterblock 2, and a fan 21 is installed on the top of waterblock 2. The waterblock 2 together with input and output pipes 24, 25, another radiator 4, a fan 3, and a pump 1 construct a complete liquid cooled circulating thermal dissipation system. The waterblock 2 according to the present invention includes a fan 21, a body 23, and an upper cover 22, in which the body 23 is a container with a containing slot 231. The containing slot 231 contains liquid such that, when its bottom is attached to chip 5, the thermal is ex changed, and the liquid is circulated through input and output pipes 24, 25.

Further, multiple upper conductivities 221 are setted on the top of the upper cover 22 while multiple lower conductivities 222 are setted beneath the bottom of the upper cover 22 and contained in the containing slot 231 of the body 23. As the body 23 of waterblock is attached and contacted to the operating chip 5, part of the thermal generated by operating chip 5 is brought by the lower conductivities 222 through the upper conductivities 221 on the surface of the upper cover 22, and is dissipated by fan 21, while the rest of thermal is conducted through the lower conductivities 222 to liquid, and by way of the pump, the liquid is circulated through input and output pipes 24, 25, and then sent to radiator 4 for thermal exchange.

As shown in the figure, the upper and the lower conductivities 221, 222 are formed in a structure of cylinders in order to effectively conduct thermal. However, those conductivities can be embodied into structures of cylinders, hollow cylinders, or fins. The present invention only discloses one of those embodiments.

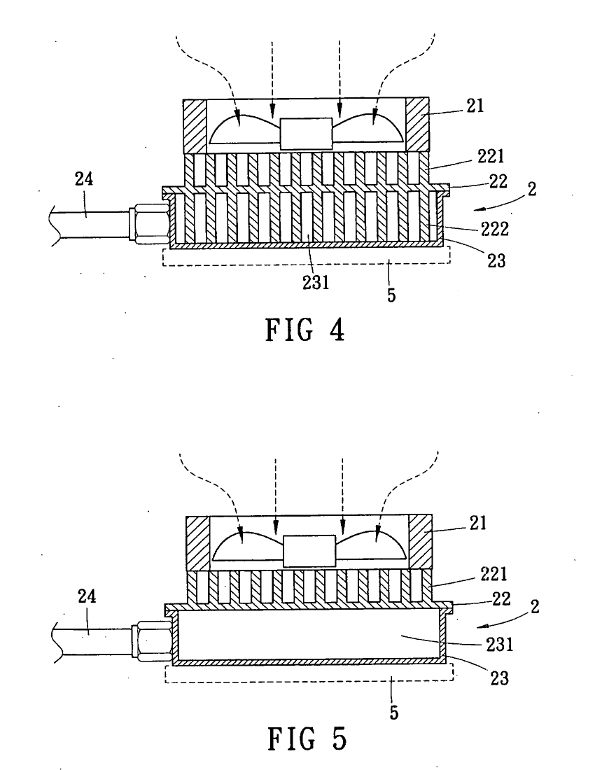

Further, referring to FIG. 4, as the body 23 of waterblock is mated and contacted to the operating chip 5, when system is active, the thermal generated by the operating chip 5 and conducted to the bottom of waterblock can be effectively conducted to the lower conductivities 222. After that, part of the thermal is conducted through the upper conductivities 221 on the surface of the upper cover 22, and is dissipated by fan 21, while the rest of thermal is conducted through the lower conductivities 222 to liquid, where liquid is circulated by the pump and sent through input and output pipes 24, 25 to radiator 4 for thermal exchange.

To summary, in the whole liquid cooled thermal dissipation system, waterblock 2 not only keeps liquid such that it is sent to radiator 4 for thermal dissipation, but utilizes the design of the upper and lower conductivities 221, 222 at the upper cover 22 and the fan 21 to enforce thermal dissipation as well. Therefore, a first cooling step is carried out immediately next to the thermal source, and then liquid is sent to radiator 4 for carrying out the second cooling step. Consequently, thermal can be dissipated faster, and the load of radiator 4 for thermal dissipation is relaxed, the efficiency of the whole liquid cooled thermal dissipation system is accordingly enhanced.

Referring to FIG. 5, which shows that the upper cover 22 of waterblock 2 according to the present invention can be embodied just with the upper conductivities 221 such that liquid contacts the bottom of the upper cover 22. The thermal thus can also be conducted to the upper conductivities 221 and then dissipated by the fan 21.

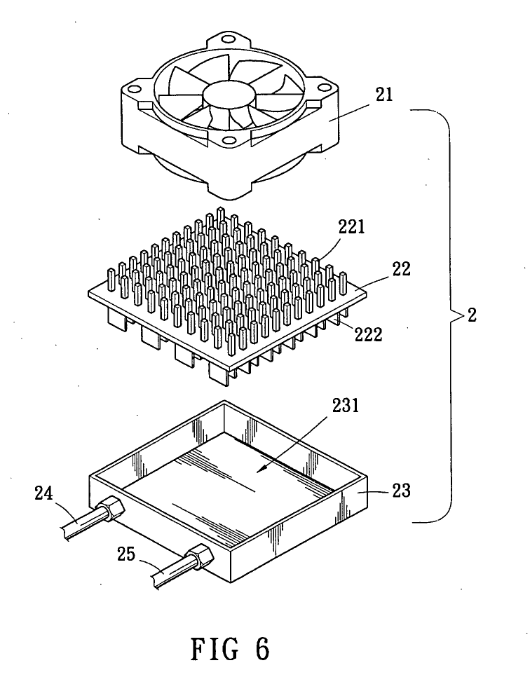

Furthermore, referring to FIG. 6, which shows an embodiment of the conductivities according to the present invention, in which the lower conductivities 222 can be embodied into structure of miscellaneous sharp of fins.

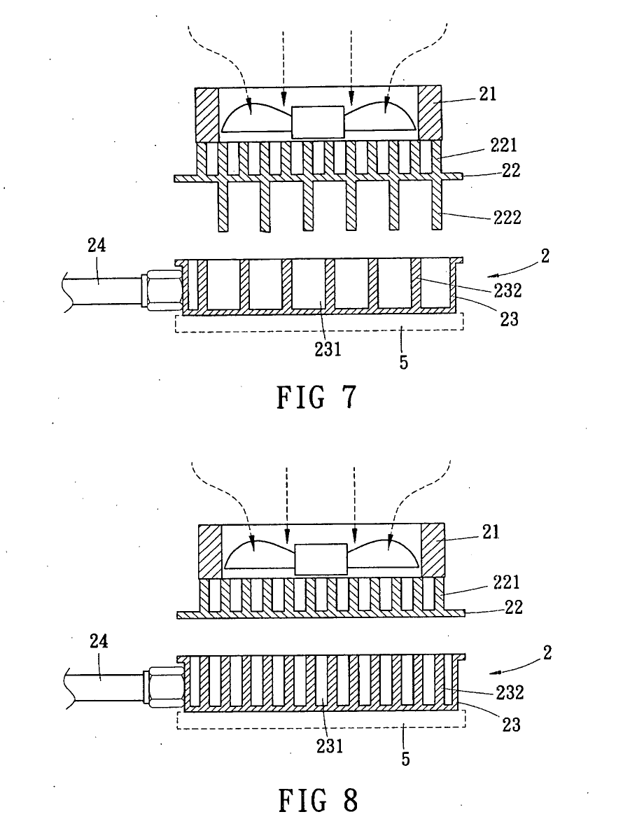

Moreover, referring to FIG. 7, which shows a sectional side view of another embodiment of the lower conductivities according to the present invention, in which the lower conductivities 222 are interlaced to the conductivities 232 inside the body 23, and a gap is kept between each lower conductivities 222 and conductivities 232, such that liquid flows between fins and performs thermal exchange efficiently.

Further, referring to FIG. 8, which shows yet a sectional side view another embodiment according to the present invention, in which conductivities 232 are setted inside the body 23, and one end of each conductivity 232 is contacted to the bottom of the upper cover 22 while a gap is kept between conductivities 232, such that liquid flows in the gaps and performs thermal exchange efficiently.

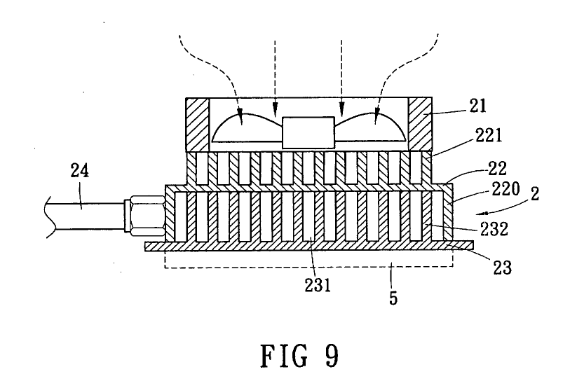

In addition, referring to FIG. 9, which shows a sectional side view a embodiment of the upper cover according to the present invention, in which the upper cover can be formed into a concave cover with its bottom upwards, while multiple conductivities 232 are installed at the body 23 with one end of each conductivity 232 contacting to the upper cover 22, and a gap is kept between conductivities 232, such that liquid performs thermal exchange in the gaps efficiently.

1. A structure of liquid cooled waterblock with thermal conductivities, which is used in the liquid cooled thermal dissipation system for chip of computer's main unit, and is attached on the chip to perform thermal exchange and thus dissipate thermal, in which the waterblock includes:
an upper cover, which is made from materials of good heat-conductivity and is setted with multiple upper and lower conductivities;
a body, which is a container made from materials of good heat-conductivity, and a containing slot is therein formed, the said containing slot is used for storing liquid to perform thermal conduction; and
a fan, which is installed at the top of the upper cover to enforce thermal exchange.

2. A structure of liquid cooled waterblock with thermal conductivities as claimed in claim 1, wherein the upper and lower conductivities can be embodied into structure of pillar, and gaps are kept between pillars to improve thermal dissipation.

3. A structure of liquid cooled waterblock with thermal conductivities as claimed in claim 1, wherein the upper and lower conductivities can be embodied into structure of hollow pillars.

4. A structure of liquid cooled waterblock with thermal conductivities as claimed in claim 1, wherein the upper and lower conductivities can be embodied into structure of fins and gaps are kept between fins to improve thermal dissipation.

5. A structure of liquid cooled waterblock with thermal conductivities as claimed in claim 1, wherein the lower conductivities can be embodied into interlacing with the conductivities inside the body, and gaps are kept between each lower conductivities and each conductivities.

6. A structure of liquid cooled waterblock with thermal conductivities as claimed in claim 1, wherein the upper cover can be embodied into a concave cover with its bottom upwards while multiple conductivities are setted in the body to contact to the upper cover, and gaps are kept between conductivities such that liquid performs thermal exchange between gaps efficiently.
